(19) United States
(12) Patent Application Publication
(10) Pub. No.: US 2025/0279026 A1
(43) Pub. Date: Sep. 4, 2025

(54) Display Device

(71) Applicant: LG Display Co., Ltd., Seoul (KR)

(72) Inventors: SeongYeong Kim, Busan (KR); ChangSoo Kim, Paju-si (KR); JeongOk Jo, Seoul (KR); Kwanghyun Choi, Seoul (KR); Jieun Oh, Seoul (KR)

(21) Appl. No.: 19/062,649

(22) Filed: Feb. 25, 2025

(30) Foreign Application Priority Data
Feb. 29, 2024 (KR) 10-2024-0029386

(51) Int. Cl. G09G 3/20; G06F 3/041; G09G 3/3233

(52) U.S. Cl. CPC G09G 3/2074; G06F 3/0412; G09G 3/3233; G09G 2300/0465; G09G 2300/0804; G09G 2300/0819; G09G 2300/0842; G09G 2300/0861; G09G 2310/06; G09G 2310/08; G09G 2320/0233; G09G 2320/028; G09G 2320/068; G09G 2330/023; G09G 2354/00

(57) ABSTRACT

Provided is a display device. The display device includes a first pixel and a second pixel disposed at a display panel, the first pixel and the second pixel comprising a plurality of sub pixels respectively, and each of the plurality of sub pixels of the second pixel comprising a plurality of lenses refracting light from an emitting diode.

### CROSS-REFERENCE TO RELATED APPLICATION

This application claims the priority of Republic of Korea Patent Application No. 10-2024-0029386 filed on Feb. 29, 2024, which is hereby incorporated by reference in its entirety.

### BACKGROUND

### Field

The present disclosure relates to a display device, and particularly, a display device that can control a viewing angle selectively.

### Description of the Related Art

Organic light emitting diodes (OLED) as a self-emitting diode comprise an anode electrode, a cathode electrode, and an organic compound layer formed between the anode electrode and the cathode electrode. The organic compound layer is comprised of a hole transport layer (HTL), an emission layer (EML) and an electron transport layer (ETL). As a driving voltage is supplied to the anode electrode and the cathode electrode, a hole having passed through the hole transport layer (HTL) and an electron having passed through the electron transport layer (ETL) move to the emission layer (EML) to form an exciton, and as a result, the emission layer (EML) generates visible light. An active matrix-type light emitting display device comprises an organic light emitting diode (OLED) emitting light on its own, and thanks to its advantages such as a rapid response speed, emission efficiency, luminance and a viewing angle, is widely used.

In a display device, pixels respectively comprising an organic light emitting diode are arranged in a matrix form, and the luminance of the pixels is adjusted in accordance with gradation of video data.

Additionally, with the advancement in modern technologies, display devices are used in various ways to provide information to the user. Display devices are included in a variety of electronic devices that require high technologies, confirm an input of the user and provide information in response to the confirmed input, as well as an electronic signboard that simply delivers visual information in one direction.

As described above, the viewing angle of a display device is not limited, but when necessary, needs to be limited selectively to protect privacy, information and the like.

### SUMMARY

One objective of the present disclosure is to provide a display device that can limit a viewing angle selectively.

Another objective of the present disclosure is to provide a display device that can secure improvement in a lifespan and power consumption thereof.

Another objective of the present disclosure is to provide a display device that can enhance luminance and cut-off performance of a viewing angle further than an existing film used to limit a viewing angle.

Yet another objective of the present disclosure is to provide a display device that can limit a viewing angle in both of a row direction and a column direction selectively while resolving shortcomings caused by separate driving.

Objects of the present disclosure are not limited to the above-mentioned objects, and other objects, which are not mentioned above, can be clearly understood by those skilled in the art from the following descriptions.

To achieve the above objectives, a display device of one embodiment comprises a first pixel and a second pixel disposed at a display panel, the first pixel and the second pixel comprising a plurality of sub pixels respectively, and each of the plurality of sub pixels of the second pixel comprising a plurality of lenses refracting light from an emitting diode.

Other detailed matters of the exemplary embodiments are included in the detailed description and the drawings.

According to the present disclosure, a display device can limit a viewing angle selectively in the case where density of lines is high making it impossible to perform separate driving in a display device using an oxide thin film transistor.

According to the present disclosure, high resolution can be embodied, and a lifespan and power consumption can improve.

The effects according to the present disclosure are not limited to the contents exemplified above, and more various effects are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a functional block diagram of a display device according to one embodiment;

FIG. 2 is a plan view of a pixel of the display device according to one embodiment;

FIG. 3 is a cross-sectional view along A-A′ of FIG. 2 according to one embodiment;

FIG. 4 is a cross-sectional view along B-B′ of FIG. 2 according to one embodiment;

FIG. 5 is a view of an exemplary sub pixel circuit that is applicable as a sub pixel circuit of the display device according to one embodiment;

FIG. 6 is a timing diagram for describing an example of driving of the display device according to one embodiment;

FIG. 7 is a plan view of an example of driving of the display device according to one embodiment;

FIGS. 8A and 8B are timing diagrams of an example of driving of the display device according to one embodiment;

FIG. 9 is a plan view of an example of driving of a display device according to another embodiment;

FIGS. 10A and 10B are timing diagrams for describing an example of driving of the display device of FIG. 9 according to one embodiment;

FIG. 11 is a plan view of an example of driving of a display device according to yet another embodiment; and

FIGS. 12A and 12B are timing diagrams for describing an example of driving of the display device of FIG. 11 according to one embodiment.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure. Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, a display device according to exemplary embodiments of the present disclosure will be described in detail with reference to accompanying drawings.

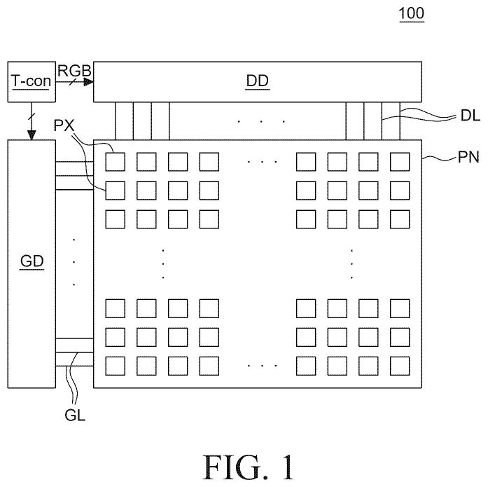

FIG. 1 is a functional block diagram of a display device according to one embodiment.

An electroluminescent display device may be applied as a display device of one embodiment. The electroluminescent display device may comprise an organic light emitting diode display device, a quantum-dot light emitting diode display device or an inorganic light emitting diode display device.

Referring to FIG. 1, a display device 100 may comprise a display panel PN, a data driving circuit DD, a gate driving circuit GD, and a timing controller T-con.

In the embodiment, the display panel PN may generate an image to be provided to the user. For example, the display panel PN may generate and display an image to be provided to the user through a plurality of pixels PX at which each pixel circuit is disposed.

The data driving circuit DD, the gate driving circuit GD, and the timing controller T-con may provide a signal for operation of each pixel PX through signal lines. The signal lines, for example, may comprise data lines DL and gate lines GL.

In some cases, the display device 100 may further comprise a power unit. At this time, a signal for the operation of a pixel PX may be provided through a power line connecting the power unit and the display panel PN. In some embodiments, the power unit may provide power to the data driving circuit DD and the gate driving circuit GD. The data driving circuit DD and the gate driving circuit GD may be driven based on power provided from the power unit.

In an example, the data driving circuit DD may supply a data signal to each pixel PX through the data lines DL, while the gate driving circuit GD may supply a gate signal to each pixel PX through the gate lines GL, and the power unit may provide a power voltage to each pixel PX through power voltage supply lines.

The timing controller T-con may control the data driving circuit DD and the gate driving circuit GD. For example, the timing controller T-con may align digital video data input from the outside again in accordance with resolution of the display panel PN and provide the signals to the data driving circuit DD.

The data driving circuit DD may convert digital video data input from the timing controller T-con, based on a data control signal, to an analogue data voltage, and provide the analogue data voltage to a plurality of data lines.

The gate driving circuit GD may generate a scan signal and an emission signal (or an emission control signal) based on a gate control signal. The gate driving circuit GD may comprise a scan driver and an emission signal driver. The scan driver may generate a scan signal in a row consecutive manner and provide the scan signal to scan lines to drive at least one or more scan lines connecting to each pixel row. The emission signal driver may generate an emission signal in a row consecutive manner and provide the emission signal to emission signal lines to drive at least one or more emission signal lines connecting to each pixel row.

In some embodiments, the gate driving circuit GD may be disposed at the display panel PN, based on the gate-driver in panel (GIP) method. For example, the gate driving circuit GD may be divided into a plurality of ones and respectively disposed on at least two lateral surfaces of the display panel PN.

A display area of the display panel PN may comprise a plurality of pixels PX. In a pixel PX, a plurality of data lines DL and a plurality of gate lines GL cross each other, and sub pixels disposed in each crossing area may be included. Each of the sub pixels included in one pixel PX may emit light of a different color. For example, the pixel PX may embody blue, red and green colors by using three sub pixels, but not be limited thereto. In some cases, the pixel PX may further comprise a sub pixel for embodying a specific color (e.g., a white color) further.

In the pixel PX, an area embodying a blue color may be referred to as a blue sub pixel, an area embodying a red color may be referred to as a red sub pixel, and an area embodying a green color may be referred to as a green sub pixel.

In one embodiment, the plurality of pixels PX may comprise a plurality of first pixels and a plurality of second pixels. The first pixels have a wide first viewing angle, and the second pixels have a limited second viewing angle. The first pixel and the second pixel respectively comprise a plurality of sub pixels. The sub pixel of the second pixel may comprise a lens limiting a viewing angle. Additionally, the term lens in the present disclosure may be used for convenience of description and may also be defined as an optical member.

A non-display area may be disposed along the perimeter of the display area. In the non-display area, a variety of elements for driving a pixel circuit disposed at a pixel PX may be disposed. For example, in the non-display area, a least part of the gate driving circuit GD may be disposed. The non-display area may also be referred to as a bezel area.

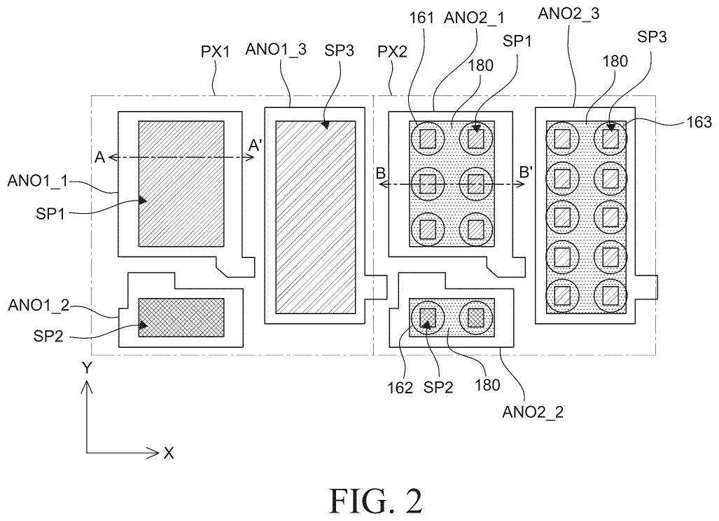

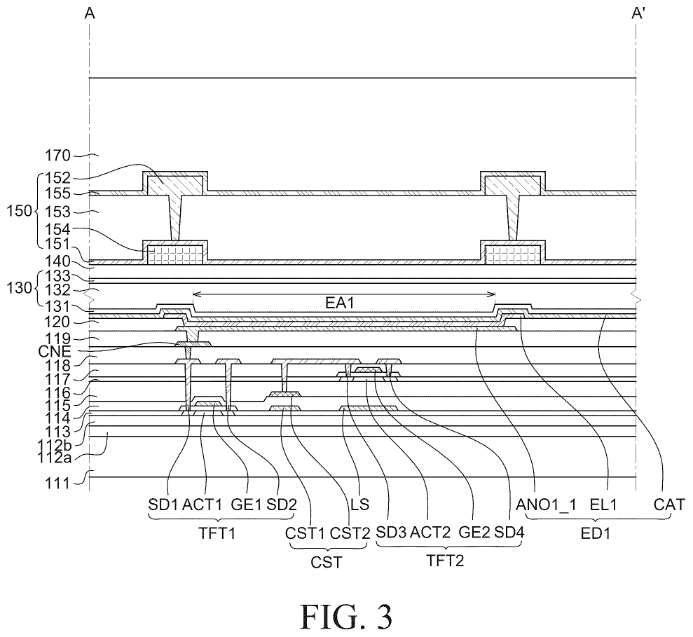

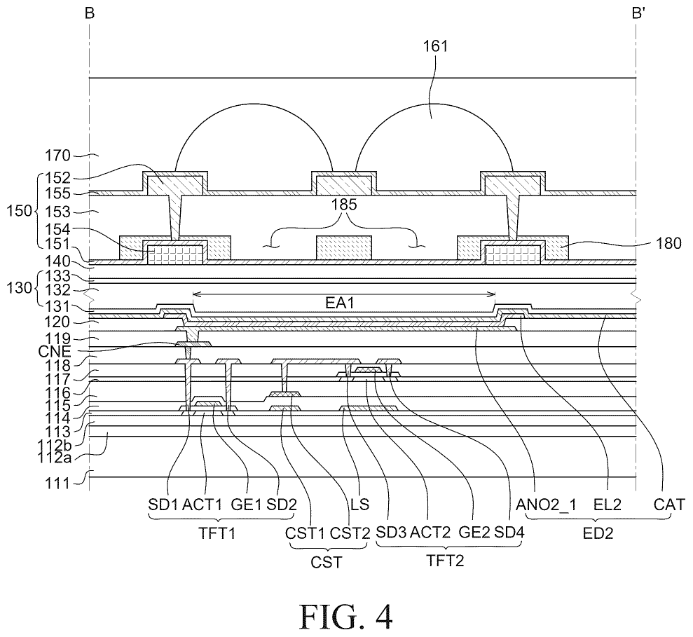

FIG. 2 is a plan view of a pixel of the display device according to one embodiment. FIG. 3 is a cross-sectional view along A-A′ of FIG. 2 according to one embodiment. FIG. 4 is a cross-sectional view along B-B′ of FIG. 2 according to one embodiment. FIG. 2 shows the planar surfaces of a first pixel PX1 and a second pixel PX2 that constitute the plurality of pixels PX of the display device 100. FIG. 3 shows the cross section of a first sub pixel SP1 of the first pixel PX1, and FIG. 4 shows the cross section of a first sub pixel SP1 of the second pixel PX2.

In FIG. 2, a first anode electrode ANO1_1, ANO1_2, ANO1_3, a second electrode ANO2_1, ANO2_2, ANO2_3, a light shielding pattern 180, and a lens 161, 162, 163 that constitute first to third sub pixels SP1, SP2, SP3 in each of the first pixel PX1 and the second pixel PX2 of the display device 100 are only illustrated.

Referring to FIG. 2, the first pixel PX1 and the second pixel PX2 may be disposed to be adjacent to each other in a row direction (an X-axis direction), but not limited thereto. The first pixel PX1 and the second pixel PX2 may also be disposed to be adjacent to each other in a column direction (a Y-axis direction). The first pixel PX1 and the second pixel PX2 constitute one repetitive pixel unit. The repetitive pixel unit is disposed in the row direction (the X-axis direction) and the column direction (the Y-axis direction) in a continuous manner. That is, the first pixel PX1 and the second pixel PX2 may be disposed alternately in the row direction (the X-axis direction).

The first pixel PX1 and the second pixel PX2 provide a different viewing angle. For example, the first pixel PX1 emits light without limiting a viewing angle, but the second pixel PX2 provides light to a specific range to limit a viewing angle. At this time, the first pixel PX1 and the second pixel PX2 may operate individually. For example, the first pixel PX1 may only be driven to embody a wide field of view mode in which a wide viewing angle is provided, and the second pixel PX2 may only be driven to embody a narrow field of view mode in which a limited viewing angle is provided. Operation methods of the first pixel PX1 and the second pixel PX2 are described hereinafter.

Each of the first pixel PX1 and the second pixel PX2 may comprise first to third sub pixels SP1, SP2, SP3, and the first sub pixel SP1 may be a green sub pixel, the second sub pixel SP2 may be a red sub pixel, and the third sub pixel SP3 may be a blue sub pixel.

The first to third sub pixels SP1, SP2, SP3 may respectively have a polygonal shape. At this time, the first to third sub pixels SP1, SP2, SP3 may have a different shape, but not be limited thereto in the present disclosure, and may have a variety of shapes.

The surface areas of the first to third sub pixels SP1, SP2, SP3 may be determined considering the lifespan and emission efficiency of an emitting diode ED1, ED2 provided at each sub pixel SP1, SP2, SP3. For example, in the case where a red emitting diode has the greatest lifespan, the surface area of the second sub pixel SP2 may be less than the surface area of each of the first sub pixel SP1 and the third sub pixel SP3, to secure a uniform lifespan, but not limited thereto. A ratio of the surface areas of the first to third sub pixels SP1, SP2, SP3 may differ.

Hereinafter, the structure of the first pixel PX1 is described with reference to FIG. 3 together.

Referring to FIGS. 2 and 3 together, the display device 100 of the embodiment may comprise a substrate 111, a first thin film transistor TFT1, a second thin film transistor TFT2, a first emitting diode ED1, an encapsulation part 130, a touch sensing part 150 and a lens protective layer 170.

FIG. 3 is a cross-sectional view showing two thin film transistors TFT1, TFT2 and one capacitor CST. The two thin film transistors TFT1, TFT2 comprises any one thin film transistor of a switching thin film transistor or a driving transistor comprising a polycrystalline semiconductor material, and an oxide thin film transistor comprising an oxide semiconductor material. At this time, a thin film transistor comprising a polycrystalline semiconductor material is referred to as a polycrystalline thin film transistor TFT1, and a thin film transistor comprising an oxide semiconductor material is referred to as an oxide thin film transistor TFT2.

In FIG. 3, the polycrystalline thin film transistor TFT1 is an emission switching thin film transistor connecting to a first emitting diode ED1, and the oxide thin film transistor TFT2 is any one switching thin film transistor connecting to a capacitor CST.

The first pixel PX1 comprises a pixel driving circuit that provides driving current to the first emitting diode ED1. The pixel driving circuit is disposed on the substrate 111, and the first emitting diode ED1 is disposed on the pixel driving circuit. Additionally, the encapsulation part 130 is disposed on the first emitting diode ED1. The encapsulation part 130 protects the first emitting diode ED1.

The pixel driving circuit may refer to one pixel array part comprising a driving thin film transistor, a switching thin film transistor and a capacitor. Additionally, the first emitting diode ED1 may refer to an array part for emitting light, which comprises a first anode electrode ANO1_1, a cathode electrode CAT and a first emission layer EL1 disposed between the first anode electrode ANO1_1 and the cathode electrode CAT.

In one embodiment, the driving thin film transistor and at least one switching thin film transistor use an oxide semiconductor as an active layer. In a thin film transistor using an oxide semiconductor material as an active layer, leakage current may be blocked more excellently, and less manufacturing costs may be incurred than in a thin film transistor using a polycrystalline semiconductor material as an active layer. Accordingly, a pixel driving circuit of one embodiment comprises a driving thin film transistor and at least one switching thin film transistor using an oxide semiconductor material to reduce power consumption and manufacturing costs.

All the thin film transistors constituting the pixel driving circuit may be embodied using an oxide semiconductor material, or part of the switching thin transistors may only be embodied using an oxide semiconductor material.

However, a thin film transistor using an oxide semiconductor material is rarely reliable, and a thin film transistor using a polycrystalline semiconductor material secures a fast operation speed and excellent reliability. Accordingly, in one embodiment, a switching thin film transistor using an oxide semiconductor material, and a switching thin film transistor using a polycrystalline semiconductor material are both included.

The substrate 111 may comprise an insulation material. The substrate 111 may comprise a transparent material. For example, the substrate 111 may comprise glass or plastic. Additionally, the substrate 111 may have a multi-layer structure in which an organic film and an inorganic film are alternately stacked. For example, the substrate 111 may be formed in such a way that a film of an organic material such as polyimide, and a film of an inorganic material such as silicon dioxide (SiO2) are alternately stacked.

A lower buffer layer 112a is formed on the substrate 111. The lower buffer layer 112a is to block moisture and the like that may infiltrate from the outside, and the lower buffer layer 112a may be used by stacking a silicon dioxide (SiO2) layer and the like is stacked in multiple layers. An auxiliary buffer layer 112b may be further disposed on the lower buffer layer 112a to protect an emitting diode from infiltration of moisture.

The polycrystalline thin film transistor TFT1 is formed on the substrate 111. The polycrystalline thin film transistor TFT1 may use a polycrystalline semiconductor as an active layer. The polycrystalline thin film transistor TFT1 comprises a first active layer ACT1 comprising a channel through which an electron or a hole moves, a first gate electrode GE1, a first source electrode SD1 and a first drain electrode SD2.

The first active layer ACT1 comprise a first channel area, a first source area that is disposed at one side of the first channel area with the first channel area between the first active layer ACT1 and the first source area, and a first drain area disposed at the other side of the first active layer ACT1.

The first source area and the first drain area are areas where a predetermined concentration of an impurity ion classified as class 5 or 3, e.g., phosphorous (P) or boron (B), is doped to a genuine polycrystalline semiconductor material and which becomes conductive. The first channel area is to maintain a genuine state of a polycrystalline semiconductor material and provides a path in which an electron or a hole moves.

Additionally, the polycrystalline thin film transistor TFT1 comprises a first gate electrode GE1 that overlaps the first channel area of the first active layer ACT1. A first gate insulation layer 113 is disposed between the first gate electrode GE1 and the first active layer ACT1. The first gate insulation layer 113 may be used by stacking an inorganic layer such as a silicon oxide (SiO2) film, a silicon nitride (SiNx) film and the like in a single layer or multiple layers.

In one embodiment, the polycrystalline thin film transistor TFT1 has a top gate structure in which the first gate electrode GEL is disposed on the first active layer ACT1. Accordingly, a first electrode CST1 included in the capacitor CST and a light shielding layer LS included in the oxide thin film transistor TFT2 may be formed of the same material as the first gate electrode GE1. The first gate electrode GE1, the first electrode CST1 and the light shielding layer LS are formed in a single mask process, resulting in a reduction in the number of mask processes.

The first gate electrode GE1 may be made of a metallic material. For example, the first gate electrode GE1 may have a single-layer structure or a multi-layer structure which is comprised of any one of molybdenum (Mo), aluminum (Al), chromium (Cr), gold (Au), titanium (Ti), nickel (Ni), neodymium (Nd) and copper (Cu) or an alloy thereof, but not be limited thereto.

A first interlayer insulation layer 114 is disposed on the first gate electrode GE1. The first interlayer insulation layer 114 may be embodied using silicon oxide (SiO2), silicon nitride (SiNx) and the like.

The display device 100 may further comprise an upper buffer layer 115, a second gate insulation layer 116 and a second interlayer insulation layer 117 that are disposed on the first interlayer insulation layer 114 in order, and the polycrystalline thin film transistor TFT1 comprises a first source electrode SD1 and a first drain electrode SD2 that are formed on the second interlayer insulation layer 117 and respectively connect to the first source area and the first drain area.

The first source electrode SD1 and the first drain electrode SD2 may have a single-layer structure or a multi-layer structure which is comprised of any one of molybdenum (Mo), aluminum (Al), chromium (Cr), gold (Au), titanium (Ti), nickel (Ni), neodymium (Nd) and copper (Cu) or an alloy thereof, but not be limited thereto.

The upper buffer layer 115 separates a second active layer ACT2 of the oxide thin film transistor TFT2 embodied using an oxide semiconductor material from the first active layer ACT1 embodied using a polycrystalline semiconductor material, and provides a base for forming the second active layer ACT2.

The second gate insulation layer 116 covers the second active layer ACT2 of the oxide thin film transistor TFT2. The second gate insulation layer 116 is formed on the second active layer ACT2 embodied using an oxide semiconductor material and embodied as an inorganic film. For example, the second gate insulation layer 116 may be silicon oxide (SiO2), silicon nitride (SiNx) and the like.

A second gate electrode GE2 is made of a metallic material. For example, the second gate electrode GE2 may have a single-layer structure or a multi-layer structure which is comprised of any one of molybdenum (Mo), aluminum (Al), chromium (Cr), gold (Au), titanium (Ti), nickel (Ni), neodymium (Nd) and copper (Cu) or an alloy thereof, but not be limited thereto.

Additionally, the oxide thin film transistor TFT2 comprises a second active layer ACT2 formed on the upper buffer layer 115 and embodied using an oxide semiconductor material, a second gate electrode GE2 disposed on the second gate insulation layer 116, and a second source electrode SD3 and a second drain electrode SD4 disposed on the second interlayer insulation layer 117.

The second active layer ACT2 comprises a genuine second channel area that is embodied using an oxide semiconductor material and not doped with impurities, and a second source area and a second drain area that are doped with impurities and become conductive.

The oxide thin film transistor TFT2 further comprises a light shielding layer LS that is disposed under the upper buffer layer 115 and overlaps the second active layer ACT2. The light shielding layer LS may block light input to an active layer 401 and secure the reliability of the oxide thin film transistor TFT2. The light shielding layer LS may be formed of the same material as the first gate electrode GE1 and formed on the upper surface of the first gate insulation layer 113. The light shielding layer LS may connect to the second gate electrode GE2 electrically to constitute a dual gate.

The second source electrode SD3 and the second drain electrode SD4 are formed of the same material, on the second interlayer insulation layer 117, at the same time, together with the first source electrode SD1 and the first drain electrode SD2, resulting in a decrease in the number of mask processes.

Additionally, a second electrode CST2 is disposed to overlap the first electrode CST1, on the first interlayer insulation layer 114, to embody a capacitor CST. The second electrode CST2, for example, may have a single-layer structure or a multi-layer structure which is comprised of any one of molybdenum (Mo), aluminum (Al), chromium (Cr), gold (Au), titanium (Ti), nickel (Ni), neodymium (Nd) and copper (Cu) or an alloy thereof.

The capacitor CST stores a data voltage that is supplied through the data lines DL for a certain period of time, and then provides the data voltage to the first emitting diode ED1. The capacitor CST comprises two electrodes that correspond to each other, and a dielectric material that is disposed between the two electrodes. The first interlayer insulation layer 114 is disposed between the first electrode CST1 and the second electrode CST2.

The first electrode CST1 or the second electrode CST2 of the capacitor CST may electrically connect to the second source electrode SD3 or the second drain electrode SD4 of the oxide thin film transistor TFT2, but not be limited thereto, and a connection relationship of the capacitor CST may change depending on a pixel driving circuit.

Additionally, a first planarization layer 118 and a second planarization layer 119 are disposed consecutively on the pixel driving circuit, to planarize the upper end of the pixel driving circuit. The first planarization layer 118 and the second planarization layer 119 may be a film of an organic material such as polyimide or acryl resin.

The first emitting diode ED1 is formed on the second planarization layer 119.

The first emitting diode ED1 comprises a first anode electrode ANO1_1, a cathode electrode CAT, and a first emission layer EL1 disposed between the first anode electrode ANO1_1 and the cathode electrode CAT. In the case where the first emitting diode ED1 is embodied as a pixel driving circuit that commonly uses a low potential voltage connecting to the cathode electrode CAT, the first anode electrode ANO1_1 is disposed as a separate electrode for each sub pixel. If the first emitting diode ED1 is embodied as a pixel driving circuit that commonly uses a high potential voltage, the cathode electrode CAT may be disposed as a separate electrode for each sub pixel.

The first emitting diode ED1 electrically connects to a driving element through an intermediate electrode CNE disposed on the first planarization layer 118. Specifically, the first anode electrode ANO1_1 of the first emitting diode ED1, and the first source electrode SD1 of the polycrystalline thin film transistor TFT1 constituting the pixel driving circuit may be connected to each other by the intermediate electrode CNE.

The first anode electrode ANO1_1 connects to the intermediate electrode CNE that is exposed through a contact hole passing through the second planarization layer 119. Additionally, the intermediate electrode CNE connects to the first source electrode SD1 that is exposed through a contact hole passing through the first planarization layer 118.

The intermediate electrode CNE serves as a medium for connecting the first source electrode SD1 and the first anode electrode ANO1_1. The intermediate electrode CNE may be formed of a conductive material such as copper (Cu), silver (Ag), molybdenum (Mo), and titanium (Ti).

The first anode electrode ANO1_1 may have a multi-layer structure that comprises a transparent conductive film and an opaque conductive film of high reflection efficiency. The transparent conductive film may be made of a material of relatively high work function such as indium-tin-oxide (ITO) or indium-zinc oxide (IZO), and the opaque conductive film may have a single-layer structure or a multi-layer structure that comprises aluminum (Al), silver (Ag), copper (Cu), lead (Pb), molybdenum (Mo), titanium (Ti) or an alloy thereof. For example, the first anode electrode ANO1_1 may have a structure where a transparent conductive film, an opaque conductive film and a transparent conductive film are consecutively stacked, or have a structure where a transparent conductive film and an opaque conductive film are consecutively stacked.

The first emission layer EL1 is formed in such a way that a hole relevant layer, an organic emission layer and an electron relevant layer are stacked on the first anode electrode ANO1_1 consecutively or reversely.

A bank layer 120 may be a pixel defining film that exposes the first anode electrode ANO1_1 of each sub pixel and defines an emission area EA1. The bank layer 120 may be formed of an opaque material (e.g., a black material) to prevent optical interference between adjacent sub pixels. At this time, the bank layer 120 comprises a light shielding material made of at least any one of a color pigment, an organic black and carbon. A spacer may be further disposed on the bank layer 120.

The cathode electrode CAT is formed on the upper surface and the lateral surface of the first emission layer EL1 while facing the first anode electrode ANO1_1, with the first emission layer EL1 between the cathode electrode CAT and the first anode electrode ANO1_1. The cathode electrode CAT may be integrally formed in the display area entirely. In the case where the cathode electrode CAT is applied to a top emission organic light emitting display device, the cathode electrode CAT may be comprised of a film of a transparent conductive material such as indium-tin oxide (ITO) or indium-zinc oxide (IZO).

The encapsulation part 130 is formed substantially on the front surface of the substrate 111, on the cathode electrode CAT. The encapsulation part 130 prevents moisture or oxygen from infiltrating into the emitting diode from the outside.

The encapsulation part 130 may have a multi-layer structure. For example, the encapsulation part 130 may comprise a first encapsulation layer 131, a second encapsulation layer 132 and a third encapsulation layer 133 that are stacked in order, but not limited thereto.

The first encapsulation layer 131 may be disposed on the first emitting diode ED1 and suppress the infiltration of moisture or oxygen. The first encapsulation layer 131 may be made of an inorganic material such as silicon oxide (SiOX), silicon nitride (SiNx), silicon oxynitride (SiNxOy) or aluminum oxide (AlyOz) and the like, but not limited thereto.

The second encapsulation layer 132 is disposed on the first encapsulation layer 131 and planarizes the surface thereof. Additionally, the second encapsulation layer 132 may cover foreign substances or particles that may be generated during manufacturing. The second encapsulation layer 132 may be made of an organic material, e.g., silicon oxycarbon (SiOxCz), acryl or epoxy-based resin and the like, but not limited thereto.

The third encapsulation layer 133 may be disposed on the second encapsulation layer 132, and like the first encapsulation layer 131, may suppress the infiltration of moisture or oxygen. At this time, the third encapsulation layer 133 and the first encapsulation layer 131 may be formed to seal the second encapsulation layer 132. Accordingly, moisture or oxygen infiltrating into an emitting diode ED1 may be reduced effectively by the third encapsulation layer 133. The third encapsulation layer 133 may be made of an inorganic material such as silicon oxide (SiOX), silicon nitride (SiNx), silicon oxynitride (SiNxOy) or aluminum oxide (AlyOz) and the like, but not limited thereto.

A touch buffer layer 140 may be disposed on the encapsulation part 130. The touch buffer layer 140 may comprise an inorganic insulation material such as silicon oxide (SiOx) and silicon nitride (SiNx), and have a multi-layer structure.

A touch sensing part 150 may be disposed on the touch buffer layer 140. The touch sensing part 150 may be disposed in the display area comprising the first emitting diode ED1 and sense a touch input. The touch sensing part 150 may sense external touch information using the user's finger or a touch pen and the like. The touch sensing part 150 comprises a first inorganic insulation layer 151, a second inorganic insulation layer 155, an organic material layer 153, a bridge electrode 154 and a touch electrode 152.

The bridge electrode 154 may be disposed on the touch buffer layer 140. The bridge electrode 154 may be an element for connecting a touch electrode 152 disconnected at a point where a touch electrode 152 extending in the row direction and a touch electrode 152 extending in the column direction cross each other.

The first inorganic insulation layer 151 may be disposed on the bridge electrode 154. The first inorganic insulation layer 151 may cover the upper surface and the lateral surface of the bridge electrode 154. The first inorganic insulation layer 151 may be made of an inorganic material. For example, the inorganic insulation layer 151 may be made of an inorganic material such as silicon nitride (SiNx), silicon oxynitride (SiON) and the like, and not limited thereto.

The organic material layer 153 may be disposed on the first inorganic insulation layer 151. The organic material layer 153 may secure a gap between the first inorganic insulation layer 151 and the elements disposed thereon and be made of an organic insulation material. For example, the organic material layer 153 may be made of photo acryl or benzocyclobutene (BCB), polyimide (PI), or polyamide (PA), and not limited thereto.

The touch electrode 152 may be disposed on the organic material layer 153. The touch electrode 152 may be disposed along the upper surface of the organic material layer 153, in a plane shape. The touch electrode 152 may be disposed in the row direction and the column direction.

The second inorganic insulation layer 155 may be disposed on the touch electrode 152. The second inorganic insulation layer 155 may cover the upper surface and the lateral surface of the touch electrode 152. The second inorganic insulation layer 155 may be made of an inorganic material. For example, the second inorganic insulation layer 155 may be made of an inorganic material such as silicon nitride (SiNx), silicon oxynitride (SiON) and the like, but not limited thereto.

Though not illustrated in FIGS. 2 and 3, in the non-display area, a routing line connecting a touch electrode 152 disposed at an outermost edge of the display area up to a touch pad disposed in the non-display area may be disposed.

Referring to FIG. 3, the lens protective layer 170 is disposed on the touch sensing part 150. The lens protective layer 170 protects lenses 161, 162, 163 formed at the second pixel PX2 described hereinafter. The lens protective layer 170 may be made of an organic insulation material and have a planar upper surface. Additionally, the refractive index of the lens protective layer 170 may be less than that of a lens.

For example, the lens protective layer 170 may be made of photo acryl, benzocyclobutene (BCB), polyimide (PI), or polyamide (PA), and not limited thereto.

Hereinafter, the structure of the second pixel PX2 is described with reference to FIG. 4 together.

Referring to FIGS. 2 and 4 together, the display device 100 of the embodiment may comprise a substrate 111, a first thin film transistor TFT1, a second thin film transistor TFT2, a second emitting diode ED2, an encapsulation part 130, a touch sensing part 150, a light shielding pattern 180, a lens 161, 162, 163, and a lens protective layer 170. The structure of the second pixel PX2 is substantially the same as the structure of the first pixel PX1 illustrated in FIG. 3 except that the second pixel PX2 further comprises a light shielding pattern 180 and a lens 161, 162, 163. Accordingly, description of the repetitive elements is omitted.

Referring to FIG. 4, the light shielding pattern 180 is provided on the first inorganic insulation layer 151. The light shielding pattern 180 may be formed to correspond between the first to third sub pixels SP1, SP2, SP3 that are adjacent to each other or disposed to overlap the bridge electrode 154. Additionally, the light shielding pattern 180 may be disposed in the emission area EA2 of the second emitting diode ED2 to form a plurality of openings 185. Accordingly, the lens 161, 162, 163 described hereinafter may be disposed to correspond to the plurality of openings 185 formed by the light shielding pattern 180.

The light shielding pattern 180 may be a black matrix, and made of black resin or chromium oxide and the like.

However, since the bridge electrode 154 and the touch electrode 152 perform a light shielding function in the second pixel PX2, the light shielding pattern 180 may be omitted when necessary.

A plurality of lenses 161, 162, 163 may be placed on the touch sensing part 150.

The lens 161, 162, 163 may be placed respectively in a first sub pixel SP1, a second sub pixel SP2 and a third sub pixel SP3 of the second pixel PX2. Specifically, the lens 161, 162, 163 may be disposed to correspond to the plurality of openings 185 formed by the light shielding pattern 180 at the second pixel PX2.

Light generated by the second emitting diode ED2 of the second pixel PX2 may emit through a plurality of corresponding lens 161, 162, 163. The lens 161, 162, 163 may limit the direction of light passing through the lens 161, 162, 163 to a first direction and/or a second direction.

For example, the lens 161, 162, 163 as a half-spherical lens has a semicircle shaped cross section on a planar surface. At this time, the direction in which light emitted from the emitting diode ED2 of the first sub pixel SP1 of the second pixel PX2 proceeds may be limited to the first direction and the second direction. For example, contents provided by the lens 161, 162, 163 of the second pixel PX2 may not be shared by people around the user. That is, a narrow field of view mode in which a limited viewing angle is provided may be embodied, in the case where an image is displayed at the second pixel PX2.

Referring to FIG. 2, the plurality of lenses 161, 162, 163 comprises a first lens 161 corresponding to the first sub pixel SP1 of the second pixel PX2, a second lens 162 disposed at the second sub pixel SP2 of the second pixel PX2 and a third lens 163 disposed at the third sub pixel SP3 of the second pixel PX2. The first lens 161, the second lens 162 and the third lens 163 may respectively be disposed to overlap the emission area EA2 of each of the first to third sub pixels SP1, SP2, SP3. At the time, the size of the lens 161, 162, 163 may be less than the size of the emission area EA2. Additionally, the first lens 161, the second lens 162 and the third lens 163 may respectively be disposed to correspond to the opening 185 formed by the light shielding pattern 180 disposed at the first to third sub pixels SP1, SP2, SP3. At this time, the size of the lens 161, 162, 163 may be greater than the size of the opening 185. For example, the planar shape of the lens 161, 162, 163 and the planar shape of the opening 185 may be concentric circles. Accordingly, the efficiency of light emitted from the opening 185 of the light shielding pattern 180 may improve.

Additionally, the sizes of the first lens 161, the second lens 162 and the third lens 163 may be the same. In the case where the sizes of the first lens 161, the second lens 162 and the third lens 163 are the same, light emitted from each of the first to third sub pixels SP1, SP2, SP3 are refracted at the same angle and embody a uniform viewing angle. Referring to FIG. 2, since the surface areas of the emission areas of the first to third sub pixels SP1, SP2, SP3 at the second pixel PX2 differ, the number of the first lenses 161, the second lenses 162 and the third lenses 163 disposed respectively at the first to third sub pixels SP1, SP2, SP3 may differ. For example, the number of the third lenses 163 disposed at the third sub pixel SP3 that is a blue sub pixel may be greater than the number of the first lenses 161 disposed at the first sub pixel SP1 that is a green sub pixel, and the number of the second lenses 162 disposed at the second sub pixel SP2 that is a red sub pixel.

At the second pixel PX2, a distance between the lenses 161, 162, 163 may be 20 μm to 40 μm. In the case where a distance between the lenses 161, 162, 163 satisfies the above range, the cut-off performance of a viewing angle may improve. Specifically, light emitted from the second emitting diode ED2 may decrease significantly to 3% or less, with respect to the front surface of the display device, past a specific viewing angle, in the narrow field of view mode where the second pixel PX2 is driven. Additionally, in the case where a distance between the lenses 161, 162, 163 in the sub pixel emitting light of the same color is less than 20 μm, the cut-off performance of a viewing angle may deteriorate. For example, in the case where luminance is 3% or greater with respect to the front surface of the display device at a viewing angle of 30°, insufficient limitation performance of a viewing angle may be shown. Additionally, in the case where a distance between the lenses 161, 162, 163 disposed in two adjacent sub pixels emitting light of a different color is less than 20 μm, a color mixture may be brough about by another adjacent sub pixel, and the performance of the display device may deteriorate. Further, in the case where a distance between the lenses 161, 162, 163 is greater than 20 μm, the emission area of the sub pixel may hardly be secured sufficiently, and high resolution of the display device may hardly be embodied.

FIGS. 3 and 4 are cross-sectional views of the first sub pixel SP1, and the structures of the second sub pixel SP2 and the third sub pixel SP3 are the same as the structure of the first sub pixel SP1 except for the sizes of the emission areas and except that an anode electrode connects to a pixel circuit in the row where a corresponding pixel is disposed.

A display device of one embodiment comprises a first pixel providing a wide viewing angle and a second pixel providing a narrow viewing angle. Each of the first to third sub pixels of the first pixel does not have an individual lens, but each of the first to third sub pixels of the second pixel comprises a lens limiting a viewing angle. Accordingly, a wide viewing angle and a narrow viewing angle may be embodied based on selective driving of the first pixel and the second pixel. For example, in the case where the first pixel is only driven, a wide field of view mode in which a wide viewing angle is provided may be embodied, and in the case where the second pixel is only driven, a narrow field of view mode in which a limited viewing angle is provided may be embodied.

The display device of one embodiment may use an oxide thin film transistor and a polycrystalline silicon thin film transistor together. At this time, due to high density of lines in a circuit, it is difficult to dispose additional lines. In the case where a viewing angle limitation mode is embodied based on separate driving, a pixel opening ratio decreases. However, in the display device of one embodiment, based on a selective supply of a data voltage to the first pixel without a lens and the second pixel with a lens, a wide field of view mode and a narrow field of view mode may be embodied selectively without separate driving. Thus, the opening ratio and the resolution of a pixel may improve, thereby securing improvement in the lifespan and the power consumption of a pixel.

Hereinafter, the configuration and the driving method of a pixel circuit of the plurality of sub pixels are described specifically.

Switch elements constituting each sub pixel may be embodied as a transistor of a n-type or p-type MOSFET structure. In the embodiment hereinafter, a p-type transistor is described as an example, but not limited thereto.

Additionally, a transistor is a three-electrode element comprising a gate electrode, a source electrode and a drain electrode. The source electrode is an electrode providing a carrier to the transistor. The carrier in the transistor starts to flow from the source electrode. The drain electrode is an electrode where the carrier goes out from the transistor. That is, the carrier in the MOSFET flows from the source electrode to the drain electrode. In the case of an n-type MOSFET (NMOS), the carrier is an electron, and a voltage of the source electrode may be less than a voltage of the drain electron so that an electrode may flow from the source electron to the drain electrode. Since an electrode flows from the source electrode to the drain electrode in the n-type MOSFET, current flows from the drain electrode to the source electrode. In the p-type MOSFET (PMOS), the carrier is a hole, and a voltage of the source electrode may be greater than a voltage of the drain electrode so that a hole may flow from the source electrode to the drain electrode. Since a hole flows from the source electrode to the drain electrode in the p-type MOSFET, current flows from the source electrode to the drain electrode. It is noteworthy that the source electrode and the drain electrode of the MOSFET are not fixed. For example, the source electrode and the drain electrode of the MOSFET may change depending on a supplied voltage. In the embodiment hereinafter, the subject matter of the present disclosure shall not be limited by the source electrode and the drain electrode of the transistor.

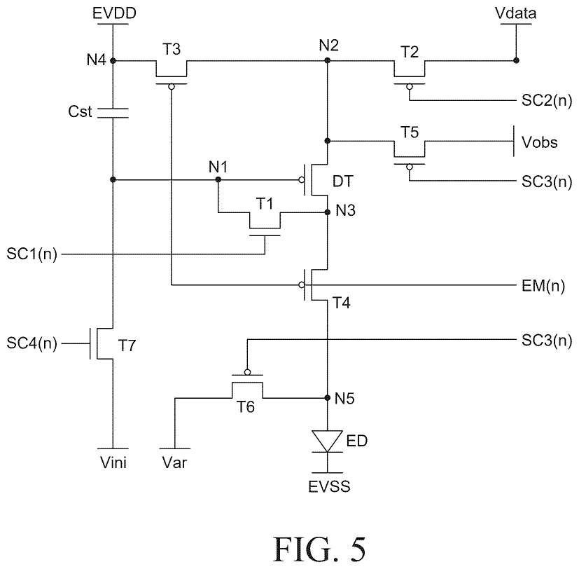

FIG. 5 is a view of an exemplary sub pixel circuit that is applicable as a sub pixel circuit of the display device according to one embodiment.

FIG. 5 shows a pixel circuit as an example for description, and the pixel circuit is not limited as long as an EM signal EM(n) is supplied to control the emission of the emitting diode ED. For example, the pixel circuit may comprise an additional scan signal, a switching thin film transistor connecting thereto, and a switching thin film transistor to which an additional initialization voltage is supplied, and in the pixel circuit, a connection relationship of a switching element or a connection position of a capacitor may vary. Hereinafter, a display device having a pixel circuit structure in FIG. 5 is described for convenience of description.

Referring to FIG. 5, each of a plurality of sub pixels may comprise a pixel circuit having a driving transistor DT, and an emitting diode ED connecting to the pixel circuit.

The pixel circuit may control driving current flowing in the emitting diode ED to drive the emitting diode ED. The pixel circuit may comprise a driving transistor DT, first to seventh transistors T1-T7 and a capacitor Cst. Each of the transistors DT, T1-T7 may comprise a first electrode, a second electrode and a gate electrode. One of the first electrode and the second electrode may be a source electrode, and the other of the first electrode and the second electrode may be a drain electrode.

Each of the transistors DT, T1-T7 may be a P-type thin film transistor or an N-type thin film transistor. In the embodiment of FIG. 5, the first transistor T1 and the seventh transistor T7 are N-type thin film transistors, and the remaining transistors DT, T2-T6 are P-type thin film transistors, but not limited thereto. In some embodiments, all or part of the transistors DT, T1-T7 may be P-type thin film transistors, or N-type thin film transistors. Additionally, the N-type thin film transistor may be an oxide thin film transistor, and the P-type thin film transistor may be a polycrystalline silicon thin film transistor.

Hereinafter, suppose that the first transistor T1 and the seventh transistor T7 are N-type thin film transistors, and the remaining transistors DT, T2-T6 are P-type thin film transistors. The first transistor T1 and the seventh transistor T7 are turned on by a high level of voltage, and the remaining transistors DT, T2-T6 are turned on by a low level of voltage.

In one example, constituting the pixel circuit, the first transistor T1 may serve as a compensation transistor, the second transistor T2 may serve as a data supply transistor, the third and fourth transistors T3, T4 may serve as an emission control transistor, the fifth transistor T5 may serve as a bias transistor, and the sixth and seventh transistors T6, T7 may serve as an initialization transistor.

The emitting diode ED may comprise an anode electrode and a cathode electrode. The anode electrode of the emitting diode ED may connect to a fifth node N5, and the cathode electrode may connect to a low potential driving voltage EVSS.

The driving transistor DT may comprise a first electrode connecting to a second node N2, a second electrode connecting to a third node N3 and a gate electrode connecting to a first node N1. The driving transistor DT may provide driving current Id to the emitting diode ED, based on a voltage of the first node N1 (or a data voltage stored in a capacitor Cst described hereinafter).

The first transistor T1 may comprise a first electrode connecting to a first node N1, a second electrode connecting to a third node N3 and a gate electrode receiving a first scan signal SC1(n). The first transistor T1 is turned on in response to the first scan signal SC1(n), and diode-connects between a data voltage Vdata (the first node N1) and the third node N3, to sample a threshold voltage Vth of the driving transistor DT. The first transistor T1 may be a compensation transistor.

The capacitor Cst may be connected or formed between the first node N1 and a fourth node N4. The capacitor Cst may store or maintain a high potential driving voltage EVDD provided.

The second transistor T2 may comprise a first electrode connecting to a data line DL (or receiving a data voltage Vdata), a second electrode connecting to a second node N2, and a gate electrode receiving a second scan signal SC2(n). The second transistor T2 may be turned on in response to the second scan signal SC2(n) and deliver a data voltage Vdata to the second node N2. The second transistor T2 may be a data supply transistor.

The third and fourth transistors T3, T4 (or first and second emission control transistors) may connect between a high potential driving voltage EVDD and the emitting diode ED, and form a current flow path in which driving current Id generated by the driving transistor DT flows.

The third transistor T3 may comprise a first electrode connecting to a fourth node N4 and receiving a high potential driving voltage EVDD, a second electrode connecting to a second node N2, and a gate electrode receiving an emission control signal EM(n).

The fourth transistor T4 may comprise a first electrode connecting to a third node N3, a second electrode connecting to a fifth node N5 (or the anode electrode of the emitting diode ED) and a gate electrode receiving an emission control signal EM(n).

The third transistor T3 and the fourth transistor T4 may be turned on in response to an emission control signal EM(n), and at this time, driving current Id may be provided to the emitting diode ED, and the emitting diode Ed may emit light with luminance corresponding to the driving current Id.

The fifth transistor T5 may comprise a first electrode receiving a bias voltage Vobs, a second electrode connecting to a second node N2, and a gate electrode receiving a third scan signal SC3(n). The fifth transistor T5 may be a bias transistor.

The sixth transistor T6 may comprise a first electrode receiving a first initialization voltage Var, a second electrode connecting to a fifth node N5 and a gate electrode receiving a third scan signal SC3(n).

The sixth transistor T6 may be turned on in response to a third scan signal SC3(n) before the emitting diode ED emits light (or after the emitting diode ED emits light), and initialize the anode electrode (or a pixel electrode) of the emitting diode ED by using a first initialization voltage Var. The emitting diode ED may have a parasitic capacitor that is formed between an anode electrode and a cathode electrode. The parasitic capacitor may be charged while the emitting diode ED emits light, so that the anode electrode of the emitting diode ED has a specific voltage. Accordingly, the first initialization voltage Var may be supplied to the anode electrode of the emitting diode ED through the sixth transistor T6, to initialize a charge amount accumulated in the emitting diode ED.

In the present disclosure, the gate electrodes of the fifth and sixth transistors T5, T6 are configured to receive a third scan signal SC3(n) commonly, but not limited thereto. The gate electrodes of the fifth and sixth transistors T5, T6 may be configured to receive an individual scan signal and be controlled independently.

The seventh transistor T7 may comprise a first electrode receiving a second initialization voltage Vini, a second electrode connecting to a first node N1, and a gate electrode receiving a fourth scan signal SC4(n).

The seventh transistor T7 may be turned on in response to a fourth scan signal SC4(n) and initialize the gate electrode of the driving transistor DT by using a second initialization voltage Vini. In the gate electrode of the driving transistor DT, unnecessary charge may remain because of a high potential driving voltage EVDD stored in the capacitor Cst. As the second initialization voltage Vini is supplied to the gate electrode of the driving transistor DT through the seventh transistor T7, a remaining charge amount may be initialized.

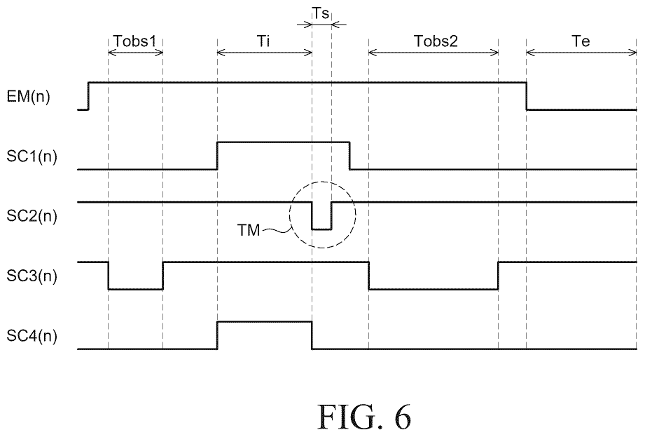

FIG. 6 is a timing diagram for describing an example of driving of the display device according to one embodiment. FIG. 6 is a view for describing a sub pixel circuit of a sub pixel and driving of an emitting diode.

Referring to FIG. 6, a sub pixel circuit may operate including at least one bias section Tobs1, Tobs2.

In at least one bias section Tobs1, Tobs2, an on bias stress operation OBS of supplying a bias voltage Vob is performed, an emission control signal EM(n) is at a high level, and the third and fourth transistors T3, T4 are turned off. A first scan signal SC1(n) and a fourth scan signal SC4(n) are at a low level, and the first transistor T1 and the seventh transistor T7 are turned off. A second scan signal SC2 is at a high level, and the second transistor T2 is turned off.

A third scan signal SC3(n) at a low level is input, and the fifth and sixth transistors T5, T6 are turned on. As the fifth transistor T5 is turned on, a bias voltage Vobs is supplied to the first electrode of the driving transistor DT connecting to the second node N2.

Herein, as the bias voltage Vobs is supplied to the third node N3 that is the drain electrode of the driving transistor DT, charge time of a voltage of the fifth node N5 that is the anode electrode of the emitting diode ED, the gate driver or a charge delay may decrease during an emission period. The driving transistor DT remains highly saturated.

For example, as the bias voltage Vobs increases, a voltage of the third node N3 that is the drain electrode of the driving transistor DT may increase, and a gate-source voltage or a drain-source voltage of the driving transistor DT may decrease. Accordingly, the bias voltage Vobs is at least greater than the data voltage Vdata, preferably.

At this time, the magnitude of drain source current Id passing through the driving transistor DT may decrease, and in a positive bias stress situation, the stress of the driving transistor DT may decrease, to resolve a charge delay of a third node N3 voltage. In other words, performing an on bias stress (OBS) operation before a threshold voltage Vth of the driving transistor DT is sampled may reduce the hysteresis of the driving transistor DT.

Accordingly, in at least one bias section Tobs1, Tobs2, the on bias stress operation may be defined as an operation of supplying a proper bias voltage directly to the driving transistor DT during non-emission periods.

Additionally, as the sixth transistor T6 is turned on in at least one bias section Tobs1, Tobs2, the anode electrode (or the pixel electrode) of the emitting diode ED connecting to the fifth node N5 is initialized to a first initialization voltage Var.

However, the gate electrodes of the fifth and sixth transistors T5, T6 may be configured to receive an individual scan signal and be controlled independently. That is, in the bias section, a bias voltage is not necessarily supplied at the same time to the first electrode of the driving transistor DT and the anode electrode of the emitting diode ED.

Referring to FIG. 6, the pixel circuit may operate comprising an initialization section Ti. The initialization section Ti is a section where a voltage of the gate electrode of the driving transistor DT is initialized.

The first scan signal SC1(n) to the fourth scan signal SC4(n) and the emission control signal EM(n) are at high levels, and the first transistor T1 and the seventh transistor T7 are turned on. The second to sixth transistors T2, T3, T4, T5, T6 are turned off. As the first and seventh transistors T1, T7 are turned on, the gate electrode and the second electrode of the driving transistor DT connecting to the first node N1 is initialized with/to a second initialization voltage Vini.

Referring to FIG. 6, the pixel circuit may operate comprising a sampling section Ts. The sampling section is a section where the threshold voltage Vth of the driving transistor DT is sampled.

The first scan signal SC1(n), the third scan signal SC3(n) and the emission control signal EM(n) are at high levels, and the second scan signal SC2(n) and the fourth scan signal SC4(n) are input at low levels. Accordingly, the third to seventh transistor T3, T4, T5, T6, T7 are turned off, the first transistor T1 remains turned on, and the second transistor T2 is turned on. That is, the second transistor T2 is turned on, a data voltage Vdata is supplied to the driving transistor DT, and the first transistor T1 diode-connects between the first node N1 and the third node N3, so that the threshold voltage Vth of the driving transistor DT is sampled.

Referring to FIG. 6, the pixel circuit may operate comprising an emission section Te. The emission section Te is a section where a sampled threshold voltage Vth is offset, and the emitting diode ED emits light with driving current corresponding to a sampled data voltage.

The emission control signal EM(n) is at a low level, and the third and fourth transistors T3, T4 are turned on.

As the third transistor T3 is turned on, a high potential driving voltage EVDD connecting to the fourth node N4 is supplied to the first electrode of the driving transistor DT connecting to the second node N2 through the third transistor T3. The driving current supplied by the driving transistor DT to the emitting diode ED via the fourth transistor T4 compensates the threshold voltage Vth of the driving transistor DT regardless of a value of the threshold voltage Vth of the driving transistor DT, and the driving transistor DT operates.

Hereinafter, the configuration and driving method of the pixel circuit depending on an arrangement structure of the first pixel PX1 and the second pixel PX2 are specifically described.

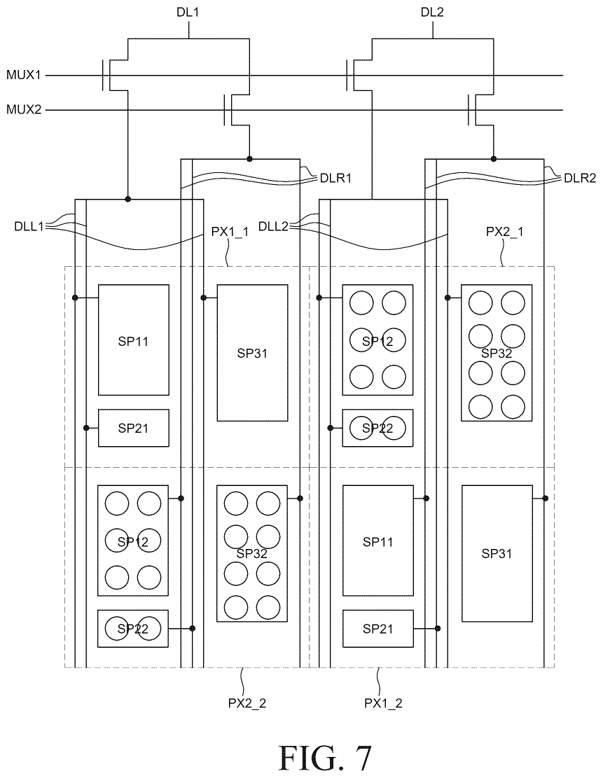

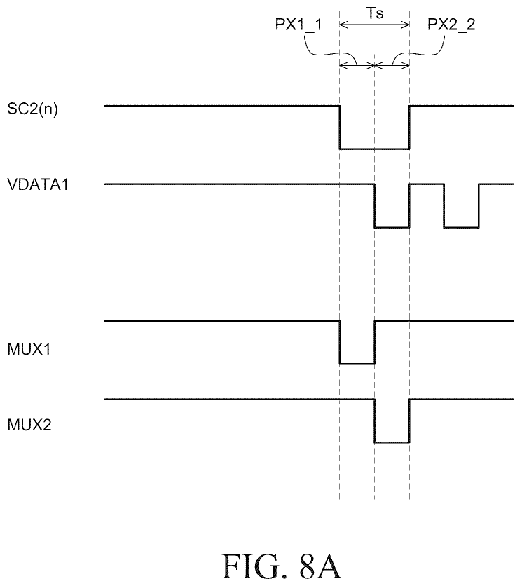

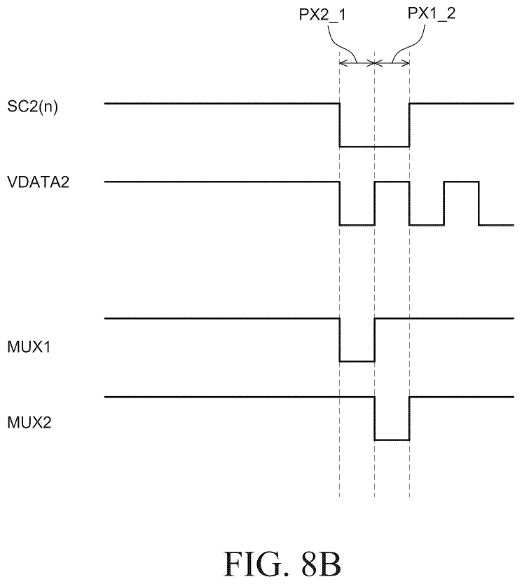

An example of driving of the display device of one embodiment is specifically described with reference to FIGS. 7-8B.

FIG. 7 is a plan view of an example of driving of the display device according to one embodiment. FIGS. 8A and 8B are timing diagrams for describing an example of driving of the display device according to one embodiment. At this time, in FIG. 7, the sub pixels of the first pixel PX1 and the second pixel PX2, the data lines and multiplexers (MUX) are only illustrated for convenience of description.

Referring to FIG. 7, the first pixel and the second pixel are arranged alternately in the column direction (the Y-axis direction), and arranged alternately in the row direction (the X-axis direction).

A first data line DL1 connects to a first column (an n^{th} column), and a second data line DL2 connects to a second column (an n+1^{th} column). Sub pixels of a first pixel PX1_1 and a second pixel PX2_2 disposed in the first column connect to the first data line DL1, and sub pixels of a second pixel PX2_1 and a first pixel PX1_2 disposed in a second column connect to the second data line DL2.

Specifically, the first data line DL1 is branched into a first left data line DLL1 and a first right data line DLR1. First to third sub pixels disposed in the first column alternately connect to the first left data line DLL1 and the first right data line DLR1. Specifically, first to third sub pixels of the first pixel PX1_1 disposed in the first column connect to the first left data line DLL1, and first to third sub pixels of the second pixel PX2_2 disposed in the first column connect to the first right data line DLR1.

Then the second data line DL2 is branched into a second left data line DLL2 and a second right data line DLR2. First to third sub pixels disposed in the second column alternately connect to the second left data line DLL2 and the second right data line DLR2. Specifically, first to third sub pixels of the second pixel PX2_1 disposed in the second column connect to the second left data line DLL2, and first to third sub pixels of the first pixel PX1_2 disposed in the second column connect to the second right data line DLR2.

Referring to FIG. 7, the display device according to the present disclosure comprises a first mux MUX1 and a second mux MUX2. The first mux MUX1 connects to the left data line DLL1, DLL2 branched from each data line, and the second mux MUX2 connects to the right data line DLR1, DLR2 branched from each data line. The first mux MUX1 delivers a left data voltage to the left data line consecutively according to a first mux MUX1 signal, and the second mux MUX2 delivers a right data voltage to the right data line consecutively according to a second mux MUX2 signal.

Accordingly, the first to third sub pixels of the first pixel PX1_1 disposed in the first column are supplied with a first data voltage from the first left data line DLL1, and the first to third sub pixels of the second pixel PX2_2 disposed in the first column are supplied with a first data voltage from the first right data line DLR1.

Similarly, the first to third sub pixels of the second pixel PX2_1 disposed in the second column are supplied with a second data voltage from the second left data line DLL2, and the first to third sub pixels of the first pixel PX1_2 disposed in the second column are supplied with a second data voltage from the second right data line DLR2.

At this time, FIGS. 8A and 8B are timing diagrams in a sampling section Ts in the case where the display device of one embodiment drives the second pixel only and embodies a narrow field of view mode. FIG. 8A is a driving timing diagram of the first pixel PX1_1 and the second pixel PX2_2 disposed in the first column, and FIG. 8B is a driving timing diagram of the second pixel PX2_1 and the first pixel PX1_2 disposed in the second column.

Referring to FIGS. 6 and 8A together, the emission control signal EM(n) is at a high level, and the second scan signal SC2(n) is input at a low level, in the sampling section Ts. At this time, the first data voltage Vdata1 is output at a high level, the first mux MUX1 is input at a low level, and the second mux MUX2 is input at a high level, so that a high level of data voltage is supplied to the first pixel PX1_1. Then the first data voltage Vdata1 is output at a low level, the first mux MUX1 is input at a high level, and the second mux MUX2 is input at a low level, so that a low level of data voltage is supplied to the second pixel PX2_2. Accordingly, the first pixel PX1_1 disposed in the first column is not driven, and the second pixel PX2_2 disposed in the first column is driven.

Similarly, referring to FIGS. 6 and 8B together, the emission control signal EM(n) is at a high level, and the second scan signal SC2(n) is input at a low level, in the sampling section Ts. At this time, the second data voltage Vdata2 is output at a low level, the first mux MUX1 is input at a low level, and the second mux MUX2 is input at a high level, so that a low level of data voltage is supplied to the second pixel PX2_1. Then the second data voltage Vdata2 is output at a high level, the first mux MUX1 is input at a high level, and the second mux MUX2 is input at a low level, so that a high level of data voltage is supplied to the first pixel PX1_2. Accordingly, the first pixel PX1_2 disposed in the second column is not driven, and the second pixel PX2_1 disposed in the second column is driven.

Referring to FIGS. 6-8B, in the structure where the first pixel and the second pixel are alternately disposed in the column direction (the Y-axis direction) and the row direction (the X-axis direction) as illustrated in FIG. 7, as a data voltage supplied to each sub pixel is selectively input in the sampling section Ts, the second pixel is only driven while the first pixel is not driven, to embody a narrow field of view mode.

Further, in the case where the first pixel is only driven to embody a wide field of view mode in the arrangement structures of the first pixel and the second pixel illustrated in FIG. 7, a data voltage of a level opposite to an input level of the data voltage illustrated in FIGS. 8A and 8B may be supplied in the sampling section Ts.

Accordingly, in the arrangement structures of the first pixel and the second pixel illustrated in FIG. 7, the first data voltage Vdata supplied to the first data line DL1, and the second data voltage Vdata2 supplied to the second data line DL2 are output at an opposite level in the sampling section Ts, and the voltage levels of the first data voltage Vdata1 and the second data voltage Vdata2 change to drive the first pixel and the second pixel selectively in the sampling section Ts.

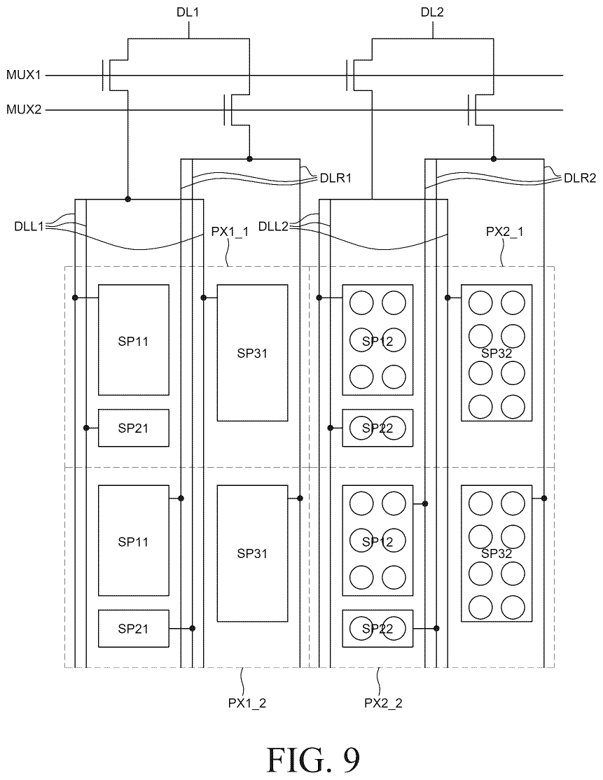

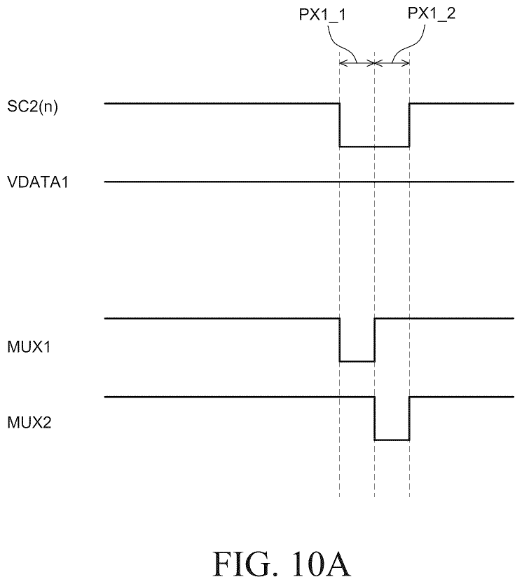

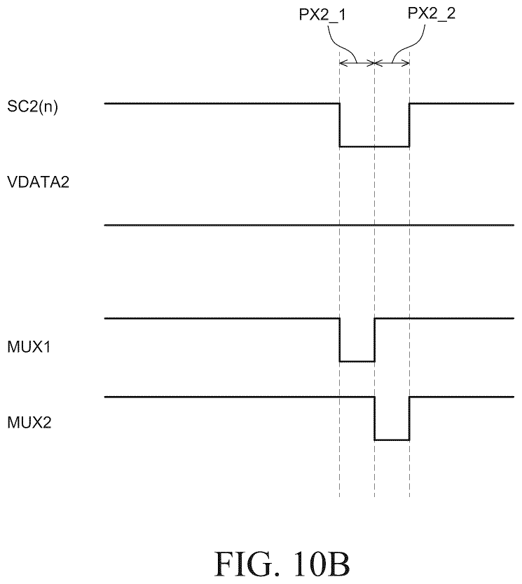

Then an example of driving of a display device of another embodiment is specifically described with reference to FIGS. 9-10B.

FIG. 9 is a plan view of an example of driving of a display device according to another embodiment. FIGS. 10A and 10B are timing diagrams for describing an example of driving of the display device according to another embodiment. At this time, in FIG. 9, sub pixels of a first pixel and a second pixel, data lines and a mux MUX are only illustrated for convenience of description.

Referring to FIG. 9, the first pixel and the second pixel are alternately disposed in the row direction (the X-axis direction), and are respectively disposed in a continuous manner in the column direction (the Y-axis direction).

As shown in FIG. 9, a first data line DL1 connects to a first column, and a second data line DL2 connects to a second column. Sub pixels of two first pixels PX1_1, PX1_2 disposed in the first column connect to the first data line DL1, and sub pixels of two second pixels PX2_1, PX2_2 disposed in the second column connect to the second data line DL2.

As shown in FIG. 9, the first data line DL1 is branched into a first left data line DLL1 and a first right data line DLR1. First to third sub pixels disposed in the first column alternately connect to the first left data line DLL1 and the first right data line DLR1. Specifically, first to third sub pixels of a first first pixel PX1_1 disposed in the first column connect to the first left data line DLL1, and first to third sub pixels of the second first pixel PX1_2 disposed in the first column connect to the first right data line DLR1.

Then the second data line DL2 is branched into a second left data line DLL2 and a second right data line DLR2. First to third sub pixels disposed in the second column alternately connect to the second left data line DLL2 and the second right data line DLR2. Specifically, first to third sub pixels of a first second pixel PX2_1 disposed in the second column connect to the second left data line DLL2, and first to third sub pixels of a second second pixel PX2_2 disposed in the second column connect to the second right data line DLR2.

Referring to FIG. 9, the display device according to the present disclosure comprises a plurality of first muxes MUX1 and second muxes MUX2. The first mux MUX1 connects to the left data line DLL1, DLL2 branched from each data line DL1, DL2, and the second mux MUX2 connects to the right data line DLR1, DLR2 branched from each data line. The first mux MUX1 delivers a left data voltage to the left data line DLL1, DLL2 consecutively according to a first mux MUX1 signal, and the second mux MUX2 delivers a right data voltage to the right data line DLR1, DLR2 consecutively according to a second mux MUX2 signal.

Accordingly, the first to third sub pixels of the first first pixel PX1_1 disposed in the first column are supplied with a first data voltage Vdata1 from the first left data line DLL1, and the second first pixel PX1_2 disposed in the first column are supplied with a first data voltage Vdata1 from the first right data line DLR1.

Similarly, the first to third sub pixels of the first second pixel PX2_1 disposed in the second column are supplied with a second data voltage Vdata2 from the second left data line DLL2, and the second second pixel PX2_2 disposed in the second column are supplied with a second data voltage Vdata2 from the second right data line DLR2.

At this time, FIGS. 10A and 10B are timing diagrams in a sampling section Ts in the case where the display device of another embodiment drives the second pixel only and embodies a narrow field of view mode. FIG. 10A is a driving timing diagram of the first pixel PX1_1, PX1_2 disposed in the first column, and FIG. 10B is a driving timing diagram of the second pixel PX2_1, PX2_2 disposed in the second column.

Referring to FIGS. 6 and 10A together, an emission control signal EM(n) is at a high level, and a second scan signal SC2(n) is input at a low level in the sampling section Ts. At this time, the first data voltage Vdata1 is output at a high level, the first mux MUX1 is input at a low level, and the second mux MUX2 is input at a high level, so that a high level of the first data voltage Vdata1 is supplied to the first first pixel PX1_1. Then the first data voltage Vdata1 remains at a high level, the first mux MUX1 is input at a high level, and the second mux MUX2 is input at a low level, so that a high level of the first data voltage Vdata1 is supplied to the second first pixel PX1_2. Accordingly, the two first pixels PX1_1, PX1_2 disposed in the first column are both not driven.

Similarly, referring to FIGS. 6 and 10B, the emission control signal EM(n) is at a high level, and the second scan signal SC2(n) is input at a low level in the sampling section Ts. At this time, the second data voltage Vdata2 is output at a low level, the first mux MUX1 is input at a low level, and the second mux MUX2 is input at a high level, so that a low level of the second data voltage Vdata2 is supplied to the first second pixel PX2_1. Then the second data voltage Vdata2 remains at a low level, the first mux MUX1 is input at a high level, and the second mux MUX2 is input at a low level, so that a low level of the second data voltage Vdata2 is supplied to the second second pixel PX2_2. Accordingly, the two second pixels PX2_1, PX2_2 disposed in the second column are both driven.

In summary, in the case where the first pixel and the second pixel in the row direction (the X-axis direction) are disposed alternately and respectively disposed in the column direction (the Y-axis direction), in a continuous manner, as illustrated in FIG. 9, the first data voltage Vdata1 and the second data voltage Vdata2 are input at an opposite level and remains constant in the sampling section Ts, so that the second pixel is only driven to embody a narrow field of view mode while the first pixel is not driven.

Additionally, in the case where a wide field of view mode is embodied by driving the first pixel only in the arrangement structures of the first pixel and the second pixel illustrated in FIG. 9, a data voltage of a level opposite to an input level of the data voltage illustrated in FIGS. 10A and 10B may be supplied in the sampling section Ts. That is, the first data voltage Vdata1 may be supplied at a low level, and the second data voltage Vdata2 may be supplied at a high level.

Accordingly, in the arrangement structures of the first pixel and the second pixel illustrated in FIG. 9, the first data voltage Vdata1 supplied to the first data line DL1, and the second data voltage Vdata supplied to the second data line DL2 are output at an opposite level in the sampling section Ts, and in the sampling section Ts, the voltage levels of the first data voltage Vdata1 and the second data voltage Vdata2 remain constant, to drive the first pixel and the second pixel selectively.

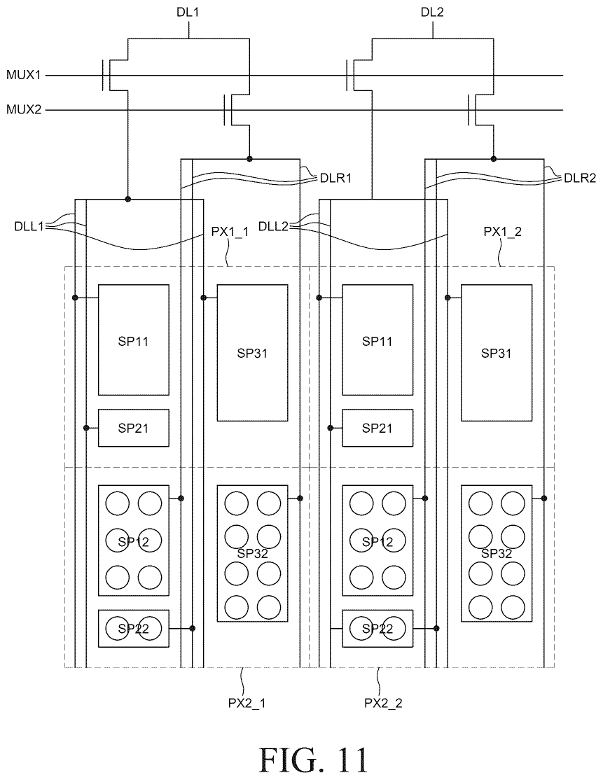

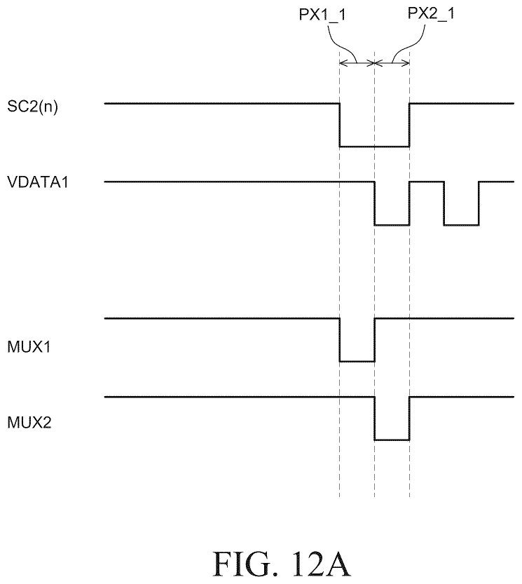

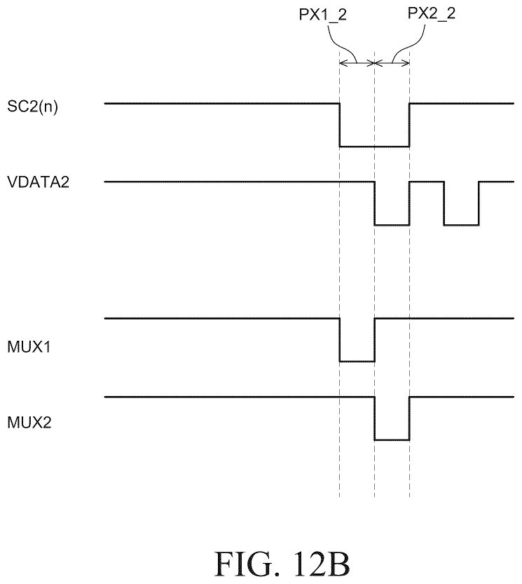

Then an example of driving of a display device of yet another embodiment is specifically described with reference to FIGS. 11 to 12B.

FIG. 11 is a plan view of an example of driving of a display device according to yet another embodiment. FIGS. 12A and 12B are timing diagrams for describing an example of driving of the display device according to yet another embodiment. At this time, in FIG. 11, sub pixels of a first pixel and a second pixel, a data line and a mux MUX are illustrated for convenience of description.

Referring to FIG. 11, a first pixel and a second pixel are alternately disposed in the column direction (the Y-axis direction), and respectively disposed in a continuous manner in the row direction (the X-axis direction) and the column direction (the Y-axis direction).

As shown in FIG. 11, a first data line DL1 connects to a first column, and a second data line DL2 connects to a second column. Sub pixels of a first pixel PX1_1 and a second pixel PX2_1 disposed in the first column connect to the first data line DL1, and subpixels of a first pixel PX1_2 and a second pixel PX2_2 disposed in the second column connect to the second data line DL2.

As shown in FIG. 11, the first data line DL1 is branched into a first left data line DLL1 and a first right data line DLR1. First to third sub pixels disposed in the first column connects to the first left data line DLL1 and the first right data line DLR1 alternately. Specifically, first to third sub pixels of the first pixel PX1_1 disposed in the first column connect to the first left data line DLL1, and first to third sub pixels of the second pixel PX2_1 disposed in the first column connect to the first right data line DLR1.

Then the second data line DL2 is branched into a second left data line DLL2 and a second right data line DLR2. First to third sub pixels disposed in the second column connect to a second left data line DLL2 and a second right data line DLR2 alternately. Specifically, first to third sub pixels of the first pixel PX1_2 disposed in the second column connect to the second left data line DLL2, and first to third sub pixels of the second pixel PX2_2 disposed in the second column connect to the second right data line DLR2.

Referring to FIG. 11, the display device according to the present disclosure comprises a plurality of first muxes MUX1 and second muxes MUX2. The first mux MUX1 connects to the left data line DLL1, DLL2 branched from each data line, and the second mux MUX2 connects to the right data line DLR1, DLR2 branched from each data line. The first mux MUX1 delivers a left data voltage to the left data line DLL1, DLL2 consecutively according to a first mux MUX1 signal, and the second mux MUX2 delivers a right data voltage to the right data line DLR1, DLR2 consecutively according to a second mux MUX2 signal.

Accordingly, the first to third sub pixels of the first pixel PX1_1 disposed in the first column are supplied with a first data voltage Vdata1 from the first left data line DLL1, and the first to third sub pixels of the second pixel PX2_1 disposed in the first column are supplied with a first data voltage Vdata1 from the first right data line DLR1.

Similarly, the first to third sub pixels of the first pixel PX1_2 disposed in the second column are supplied with a second data voltage Vdata2 from the second left data line DLL2, and the first to third sub pixels of the second pixel PX2_2 disposed in the second column are supplied with a second data voltage Vdata2 from the second right data line DLR2.

At this time, FIGS. 12A and 12B are timing diagrams in a sampling section Ts in the case where the display device of yet another embodiment drives the second pixel only and embodies a narrow field of view mode. FIG. 12A is a driving timing diagram of a first pixel PX1_1 and a second pixel PX2_1 disposed in the first column, and FIG. 12B is a driving timing diagram of a first pixel PX1_2 and a second pixel PX2_2 disposed in the second column.

Referring to FIGS. 6 and 12A, an emission control signal EM(n) is at a high level, and a second scan signal SC2(n) is input at a low level, in a sampling section Ts. At this time, a first data voltage Vdata1 is output at a high level, a first mux MUX1 is input at a low level, and a second mux MUX2 is input at a high level, so that a high level of the first data voltage Vdata1 is supplied to the first pixel PX1_1. Then the first data voltage Vdata1 is output at a low level, the first mux MUX1 is input at a high level, and the second mux MUX2 is input at a low level, so that a low level of the first data voltage Vdata1 is supplied to the second pixel PX2_1. Accordingly, the first pixel PX1_1 disposed in the first column is not driven, and the second pixel PX2_1 is driven.

Similarly, referring to FIGS. 6 and 12B together, the emission control signal EM(n) is at a high level, and the second scan signal SC2(n) is input at a low level in the sampling section Ts. At this time, a second data voltage Vdata2 is output at a high level, the first mux MUX1 is input at a low level, and the second mux MUX2 is input at a high level, so that a high level of the second data voltage Vdata2 is supplied to the first pixel PX1_2. Then the second data voltage Vdata2 is input at a low level, the first mux MUX1 is input at a high level, and the second mux MUX2 is input at a low level, so that a low level of the second data voltage Vdata2 is supplied to the second pixel PX2_2. Accordingly, the first pixel PX1_2 disposed in the second column is not driven, and the second pixel PX2_2 is driven.

In summary, in the case where the first pixel and the second pixel in the column direction (the Y-axis direction)) are disposed alternately and respectively disposed in a continuous manner, in the row direction (the X-axis direction) and the column direction (the Y-axis direction), as illustrated in FIG. 11, the first data voltage Vdata1 and the second data voltage Vdata2 are input at the same level, and a data voltage supplied to each sub pixel is input selectively, in the sampling section Ts, so that the second pixel is only driven to embody a narrow field of view mode while the first pixel is not driven.

Additionally, in the case where a wide field of view mode is embodied by driving the first pixel only in the arrangement structures of the first pixel and the second pixel illustrated in FIG. 11, a data voltage of a level opposite to an input level of the data voltage illustrated in FIGS. 12A and 12B may be supplied in the sampling section Ts. That is, in the case where the first mux MUX1 is input at a low level, the first data voltage Vdata1 and the second data voltage Vdata2 may be both supplied at a low level, and in the case where the second mux MUX2 is input at a low level, the first data voltage Vdata1 and the second data voltage Vdata2 may be both supplied at a high level.

Accordingly, in the arrangement structures of the first pixel and the second pixel illustrated in FIG. 11, the first data voltage Vdata1 supplied to the first data line DL1, and the second data voltage Vdata2 supplied to the second data line DL2 are output at the same level in the sampling section Ts, and in the sampling section Ts, the voltage levels of the first data voltage Vdata1 and the second data voltage Vdata2 change, to drive the first pixel and the second pixel selectively.

The exemplary embodiments of the present disclosure can also be described as follows:

According to an aspect of the present disclosure, there is provided a display device. The display device includes a first pixel and a second pixel being disposed at a display panel, the first pixel and the second pixel respectively comprising a plurality of sub pixels, and each of the plurality of sub pixels of the second pixel comprising a plurality of lenses refracting light from an emitting diode.

The plurality of lenses may be a half-spherical lens.

The plurality of lenses may be not disposed in the first pixel.

A distance between the plurality of lenses may be 20-40 μm.

The plurality of sub pixels may comprise a green sub pixel, a red sub pixel and a blue sub pixel. The plurality of lenses may comprise a plurality of first lenses disposed in the green sub pixel of the second pixel, a plurality of second lenses disposed in the red sub pixel of the second pixel, and a plurality of third lenses disposed in the blue sub pixel of the second pixel. The number of the plurality of first lenses may be greater than the number of the plurality of second lenses, and the number of the plurality of third lenses may be greater than the number of the first lenses.

Each of the plurality of sub pixels may comprise a first thin film transistor and a second thin film transistor; the emitting diode being disposed on the first thin film transistor and the second thin film transistor; a bank layer exposing an anode electrode of the emitting diode and defining an emission area; and an encapsulation part disposed to cover the emitting diode.

Each of the plurality of sub pixels of the second pixel, may further comprise a light shielding pattern being disposed on the encapsulation part and comprising a plurality of openings. Each of the plurality of lenses may be disposed on the light shielding pattern, to correspond to each of the plurality of openings.

Each of the plurality of sub pixels may further comprise a touch sensing part being disposed on the encapsulation part. The touch sensing part may comprise a first electrode, a second electrode on the first electrode, an organic material layer between the first electrode and the second electrode and an inorganic insulation layer on the second electrode. The light shielding pattern may be disposed under the organic material layer. And, the plurality of lenses may be disposed on the inorganic insulation layer.

Each of the plurality of lenses may have a lower surface less than a surface area of the emission area and greater than a surface area of the opening.

The first thin film transistor may comprise a first active layer made of a polycrystalline silicon semiconductor material, a first gate electrode overlapping the first active layer with a first gate insulation layer between the first gate electrode and the first active layer, and a first source electrode and a first drain electrode connecting to the first active layer. And, the second thin film transistor may comprise a second active layer made of an oxide semiconductor material, a second gate electrode overlapping the second active layer with a second gate insulation layer between the second gate electrode and the second active layer, and a second source electrode and a second drain electrode connecting to the second active layer.

The display device may further comprise a gate line extending in a row direction; and a data line extending in a column direction and crossing the gate line. The data line may be branched into a left data line and a right data line. The plurality of pixels may be arranged in the column direction and the row direction. The plurality of pixels arranged in the row direction may connect to an identical gate line, and the plurality of pixels arranged in the column direction may connect to the left data line and the right data line alternately.

The display device may further comprise a first mux and a second mux delivering a data voltage from the data line to the left data line and the right data line consecutively.

The first pixel and the second pixel may be alternately arranged in the column direction and the row direction. The data line may comprise a first data line being disposed in an nth column and a second data line disposed in an n+1 column. Each of the plurality of sub pixels may be driven separately in an initial section, a sampling section and an emission section, in the sampling section, a first data voltage supplied to the first data line may be output at a level opposite to a level of a second data voltage supplied to the second data line, and in the sampling section, voltage levels of a first data voltage and a second data voltage change.

The first pixel and the second pixel may be arranged alternately in the row direction. The first pixel and the second pixel are respectively arranged in a continuous manner in the column direction. The data line may comprise a first data line being disposed in an nth column and a second data line in an n+1 column. Each of the plurality of sub pixels may be driven separately in an initial section, a sampling section and an emission section. In the sampling section, a first data voltage supplied to the first data line may be output at a level opposite to a level of a second data voltage of the second data line. And, in the sampling section, voltage levels of a first data voltage and a second data voltage may remain constant.

The first pixel and the second pixel may be respectively arranged in a continuous manner in the row direction. The first pixel and the second pixel may be alternately arranged in the column direction. The data line may comprise a first data line disposed in an nth column and a second data line disposed in an n+1 column. Each of the plurality of sub pixels may be driven separately in an initial section, a sampling section and an emission section. In the sampling section, a first data voltage supplied to the first data line may be output at a level identical to a level of a second data voltage of the second data line. And, in the sampling section, voltage levels of a first data voltage and a second data voltage may change.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a first pixel and a second pixel being disposed at a display panel,
wherein the first pixel and the second pixel respectively comprise a plurality of sub pixels, and each of the plurality of sub pixels of the second pixel comprising a plurality of lenses that refract light from an emitting diode.

2. The display device of claim 1, wherein the plurality of lenses are a half-spherical lens.

3. The display device of claim 1, wherein the plurality of lenses are not in the first pixel.

4. The display device of claim 1, wherein a distance between the plurality of lenses is 20 μm to 40 μm.

5. The display device of claim 1, wherein the plurality of sub pixels comprise a green sub pixel, a red sub pixel and a blue sub pixel,
wherein the plurality of lenses comprise a plurality of first lenses in the green sub pixel of the second pixel, a plurality of second lenses in the red sub pixel of the second pixel, and a plurality of third lenses in the blue sub pixel of the second pixel, and
a number of the plurality of first lenses is greater than a number of the plurality of second lenses, and a number of the plurality of third lenses is greater than the number of the plurality of first lenses.

6. The display device of claim 1, wherein each of the plurality of sub pixels comprises:
a first thin film transistor and a second thin film transistor, the emitting diode disposed on the first thin film transistor and the second thin film transistor;
a bank layer exposing an anode electrode of the emitting diode, the bank layer defining an emission area; and
an encapsulation part covering the emitting diode.

7. The display device of claim 6, wherein each of the plurality of sub pixels of the second pixel, further comprises:
a light shielding pattern on the encapsulation part, the light shielding pattern and comprising a plurality of openings,
wherein each of the plurality of lenses is on the light shielding pattern and corresponds to each of the plurality of openings.

8. The display device of claim 7, wherein each of the plurality of sub pixels further comprises a touch sensing part on the encapsulation part, the touch sensing part comprising a first electrode, a second electrode on the first electrode, an organic material layer between the first electrode and the second electrode, and an inorganic insulation layer on the second electrode,
wherein the light shielding pattern is under the organic material layer, and the plurality of lenses are on the inorganic insulation layer.

9. The display device of claim 7, wherein each of the plurality of lenses has a lower surface less of a surface area than the emission area and greater than a surface area of an opening from the plurality of openings.

10. The display device of claim 6, wherein the first thin film transistor comprises a first active layer including a polycrystalline silicon semiconductor material, a first gate electrode overlapping the first active layer with a first gate insulation layer between the first gate electrode and the first active layer, and a first source electrode and a first drain electrode connecting to the first active layer, and
the second thin film transistor comprises a second active layer including an oxide semiconductor material, a second gate electrode overlapping the second active layer with a second gate insulation layer between the second gate electrode and the second active layer, and a second source electrode and a second drain electrode connecting to the second active layer.

11. The display device of claim 10, wherein each of the plurality of sub pixels further comprises a capacitor; and
a first electrode included in the capacitor and a light shielding layer included in the second thin film transistor are formed of the same material as the first gate electrode.

12. The display device of claim 1, further comprising:
a gate line extending in a row direction; and
a data line extending in a column direction and crossing the gate line,
wherein the data line is branched into a left data line and a right data line,
the plurality of sub pixels are arranged in the column direction and the row direction,
the plurality of sub pixels arranged in the row direction connect to an identical gate line, and
the plurality of sub pixels arranged in the column direction connect to the left data line and the right data line alternately.

13. The display device of claim 12, wherein the display device further comprises a first mux and a second mux delivering a data voltage from the data line to the left data line and the right data line consecutively.

14. The display device of claim 13, wherein the first pixel and the second pixel are alternately arranged in the column direction and the row direction,
the data line comprises a first data line in an n^{th} column and a second data line disposed in an n⁺¹ column,
each of the plurality of sub pixels is driven separately in an initial section, a sampling section, and an emission section,
in the sampling section, a first data voltage supplied to the first data line is output at a level opposite to a level of a second data voltage supplied to the second data line, and
in the sampling section, voltage levels of a first data voltage and a second data voltage change.

15. The display device of claim 13, wherein the first pixel and the second pixel are arranged alternately in the row direction,
the first pixel and the second pixel are respectively arranged in a continuous manner in the column direction,
the data line comprises a first data line being disposed in an n^{th} column and a second data line in an n⁺¹ column,
each of the plurality of sub pixels is driven separately in an initial section, a sampling section and an emission section,
in the sampling section, a first data voltage supplied to the first data line is output at a level opposite to a level of a second data voltage of the second data line, and
in the sampling section, voltage levels of a first data voltage and a second data voltage remain constant.

16. The display device of claim 13, wherein the first pixel and the second pixel are respectively arranged in a continuous manner in the row direction,
the first pixel and the second pixel are alternately arranged in the column direction,
the data line comprises a first data line disposed in an n^{th} column and a second data line disposed in an n⁺¹ column,
each of the plurality of sub pixels is driven separately in an initial section, a sampling section and an emission section,
in the sampling section, a first data voltage supplied to the first data line is output at a level identical to a level of a second data voltage of the second data line, and
in the sampling section, voltage levels of a first data voltage and a second data voltage change.
